(19) United States
(12) Patent Application Publication
(10) Pub. No.: US 2015/0279961 A1
(43) Pub. Date: Oct. 1, 2015

(54) METHOD OF MANUFACTURING HIGH POWER VERTICAL GaN-PIN DIODE

(71) Applicant: NATIONAL TSING HUA UNIVERSITY, Hsinchu City (TW)

(72) Inventors: CHIH-FANG HUANG, Hsinchu City (TW); TING-FU CHANG, Hsinchu City (TW); GE-CHENG LIU, Hsinchu City (TW); YU-TENG TSENG, Hsinchu City (TW); SHAO-YEN CHIU, Hsinchu City (TW)

(73) Assignee: NATIONAL TSING HUA UNIVERSITY, Hsinchu City (TW)

(21) Appl. No.: 14/230,530

(22) Filed: Mar. 31, 2014

(51) Int. Cl. H01L 29/66; H01L 21/02

(52) U.S. Cl. CPC H01L 29/66121; H01L 21/0254

(57) ABSTRACT

Compared with the typical Si and GaAs material, a wide bandgap material (III-N compound) has the better electronic properties, particularly the operation stability and the temperature sensitivity, and is extremely suitable for the high power electronic application. The invention proposes a high power vertical GaN device for providing the reverse breakdown voltage higher than or equal to 600 V, the lower on-resistance is lower than or equal to 5 mΩ-cm² and the forward current as high as 3 A/mm².

### BACKGROUND OF THE INVENTION

1. Field of the Invention

The invention relates to a method of manufacturing a high power PIN diode, and more particularly to a method of growing gallium nitride of about the thickness of 8 um as the low concentration doped layer on a sapphire substrate, wherein the reverse breakdown voltage may be higher than or equal to 600 V and the on-resistance is lower than or equal to 5 mΩ-cm².

2. Related Art

Vertical III-N power devices include power diodes and power transistors, wherein the study object of the transistor aims at the vertical trench type gate MISFET. However, the PIN diode can monitor the epitaxy quality. Only the lower dislocation defect density can cause the higher reverse breakdown voltage and the low leakage current.

Due to the excellent properties of the gallium nitride (GaN), such as the wide bandgap (˜3.4 eV), high threshold electric field (˜3 MV/cm), high electronic saturation speed (˜2.5×107 cm/s), thermal stability, chemical inertness, and the like, the III-Nitride device is regarded as one of the next generation of power device substrates. At present, the relatively popular III-N power device structure is the transversal conduction type AlGaN/GaN HEMT device, having the main features including: (1) the high concentration and the native 2DEG (n˜1×1013 cm-2, μn˜1500 cm2/V-s) of the high mobility, which are advantageous to the reduction of the on resistance; and (2) the device structure is relatively simple, and the required manufacturing technology is relatively mature. In addition, by implementing the low defect heterogeneous epitaxy to grow the III-N device on the generic substrate, such as the silicon wafer, has its advantageous cost as compared with another potential substrate SiC. However, the AlGaN/GaN HEMT has the breakdown voltage over 2000 V, the on-resistance of 14.8 mΩ-cm², the performance exceeding the silicon-based power transistor, and is a normally-on (depletion mode) device with Vₜₕ of −2.8 V.

However, the AlGaN/GaN HEMT structure accompanies some drawbacks that cannot be easily solved: (1) because it is the transversal conduction device, it needs to occupy the larger chip area, and the characteristic on-resistance (R_{on,sp}) cannot be easily decreased; (2) the native 2DEG concentration as high as about 10¹³ cm⁻² causes the negative value of the threshold voltage (Vₜₕ) of the device and thus the normally-on property; (3) because it is the surface transversal type device, its current path is very close to the surface, and any surface defect would affect the DC and switching properties of the device; and (4) the property of the surface passivation layer is very important, and affects the breakdown property and the reliability of the device. At present, there are many researches focusing at this field, but the progress is limited, the product has not been successfully introduced into the high power market yet, and the product specification is below 200 V. According the experience of the most mature silicon power device, the discrete power devices, such as UMOSFET, DMOSFET, IGBT and the like, used in most electrochemical transpiration system have the vertical structure. Therefore, it is a great advantage if the vertical type (the quasi-vertical type at the beginning) III-N devices, including diodes and transistors, can be developed. In the year of 2005, Velox company (now being merged by ST Microelectronics) in the United States implemented 600 V quasi-vertical type Schottky diode (or Schottky Barrier Diode, SBD) on the sapphire substrate, and declared that its property is equivalent to that of the silicon carbide Schottky diode but the cost can be decreased to one half that of the silicon carbide Schottky diode. At the end of 2010, Japan POWDEC used the epitaxial layer transfer technology to implement the 600 V vertical Schottky diode. In the year of 2011, the research group of Prof. Baliga of University of North Carolina disclosed that the vertical Schottky diode, which is manufactured on the bulk GaN material, has the breakdown voltage as high as 1650 V.

The development of the epitaxy and manufacturing technology is very important to the success of failure of the vertical type device. For example, the On—GaN device epitaxy technology can provide the high quality vertical type structure. The low defect heterogeneous epitaxy technology and the epitaxial layer transfer bonding technology are the keys of advancing from the quasi-vertical type to the vertical type structure. The area-selective/secondary III-N epitaxy technology, the locality doping and the activating technology are the bases of all the devices. The high quality gate dielectric layer deposit technology is the key for manufacturing the MISFET device. The implementation of the key technology needs the assistance of the material (epitaxy, process) inspecting and analyzing technology. The device application and integration of the key technology gradually implement the high power device. For the power transistor, the normally-off property is extremely important to the operation security (fail-safe) of the electric power system. The threshold voltage (Vₜₕ) of the typical 600-V Si MOSFET needs to reach 2.5 V or higher to avoid the malfunction. If the non-electroconductive substrate or buffer layer is adopted and the epitaxial layer transfer bonding technology cannot be implemented yet, then the quasi-vertical type structure is the interim target of the test process. The source (S) and the drain (D) are located on the upper surface of the device, and the limited contact surface area is considered (unlike the vertical structure wherein all the chip back can serve as the drain), and the formation of the low resistance Ohmic contact (ρ_{c}≦10⁻⁶ Ω-cm²) relies on the high-temperature (about 800° C. or higher) annealing in order not to affect the dielectric layer property of the gate (G) and in order to reserve its process flexibility.

In addition t the device epitaxy quality and the active region structure, the edge electric field suppress (edge termination) versus the high-voltage property of the device are also extremely important, particularly when the presence of the build-in polarized or piezoelectric electric field decreases the effective threshold electric field. For example, the conventional transversal device suppresses the gate end edge electric field by adopting the field plate (FP) and the recessed gate, or the diode device suppresses the active region electrode edge electric field by adopting the field plate, the junction termination extension (JTE), the guard ring, or the like. By adopting the high dielectric coefficient (High-k) FP, the maximum electric field of the junction edge of a 4H-SiC SBD can decrease from 7 MV/cm to 3.6 MV/cm, thereby making the breakdown voltage of the actual device reach 2249 V, which is about 90% of the theoretical value. The other two edge electric field suppressing technologies are JTE and the guard ring formed by the ion implantation. In addition, Japan POWDEC published a polarization junction HFET (PJ-HFET), which has the breakdown voltage reaching 6000 V and utilizes a p-GaN covering layer to make the AlGaN layer generate polarization charges and thus homogenize the electric field between the gate and the drain, in the year of 2012.

### SUMMARY OF THE INVENTION

The invention relates to a method of manufacturing a high power PIN diode, and more particularly to a method of growing gallium nitride of about the thickness of 8 um as the low concentration doped layer on a sapphire substrate, wherein the reverse breakdown voltage may be higher than or equal to 600 V and the on-resistance is lower than or equal to 5 mΩ-cm².

### BRIEF DESCRIPTION OF THE DRAWINGS

FIG. 1 shows a structure of a high power PIN gallium nitride diode.

FIG. 2 shows a finished structure of the high power PIN gallium nitride diode.

FIG. 3 shows measurement results of the high power PIN gallium nitride diode.

### DETAILED DESCRIPTION OF THE INVENTION

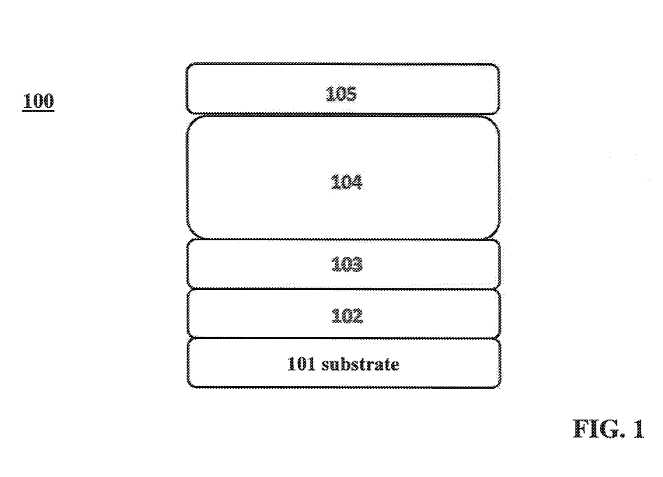

Please refer to FIG. 1, which shows flow chart of the method of manufacturing a high power PIN gallium nitride diode 100 according to an embodiment of the invention. First, a substrate 101 is provided. The substrate 101 is not particularly restricted, and may be any conventional substrate, such as silicon (Si), gallium arsenide (GaAs), sapphire, SiC substrate or the like. Also, material layers, which are not shown and serve as various active/passive devices, may be alternatively formed on the substrate. Next, as shown in FIG. 1, a gallium nitride semiconductor laminated layer 102 is formed on the substrate 101 and serves as a buffer layer. Then, a high concentration (1×10¹⁹ cm⁻³) gallium nitride semiconductor laminated layer 103 is grown on the gallium nitride semiconductor laminated layer 102. Thereafter, a low concentration (1×10¹⁶ cm⁻³) gallium nitride semiconductor laminated layer 104 (8 um) is grown. Finally, a high concentration (1×10¹⁸ cm⁻³) P gallium nitride semiconductor laminated layer 105 is grown, and the device structure is completed.

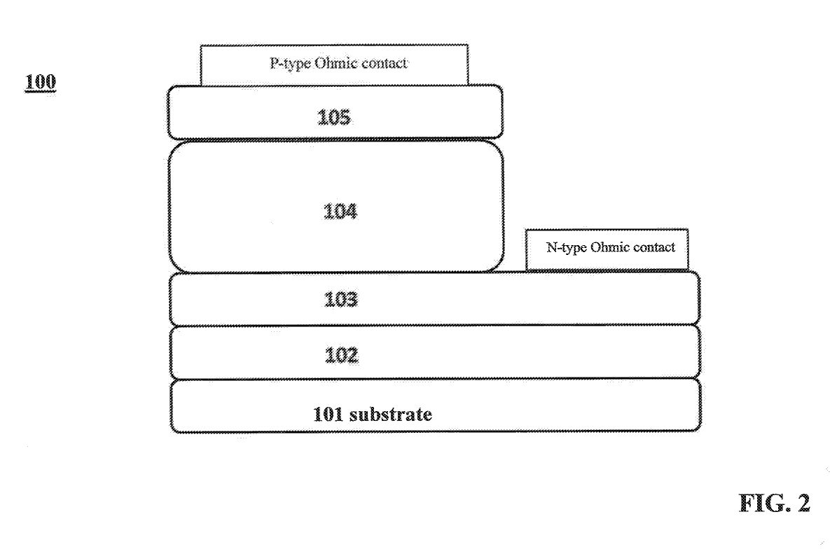

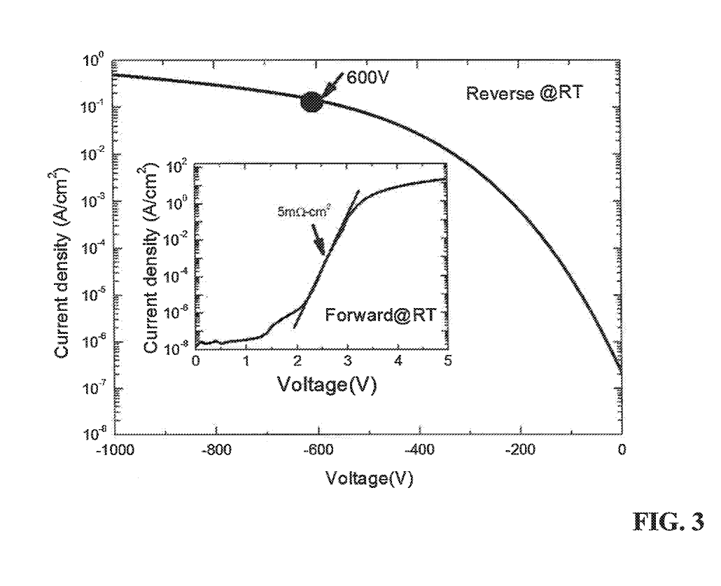

The material layers may be exposed by the essential process, such as the conventional photo-lithography, etching or the like. FIG. 2 shows the finished high power PIN gallium nitride diode. First, dry-etching is applied to the gallium nitride semiconductor laminated layer 102, alloy titanium/aluminum/titanium/gold (250 Å/1250 Å/350 Å/375 Å) is coated in a sputter, and the Ohmic contact is completed in rapid diffusion furnace (900° C.) with the nitrogen environment for 10 seconds. In addition, alloy nickel/gold (50 Å/200 Å) is coated in the sputter in the rapid diffusion furnace (500° C.) with the oxygen environment for 600 seconds to finish the Ohmic contact by the conventional photo-lithography gallium nitride semiconductor laminated layer 105. FIG. 3 shows the measured results. It is obtained that the reverse breakdown voltage is 600 V at 0.1 Å/cm², and the on-resistance is lower than or equal to 5 mΩ-cm².

What is claimed is:

1. A method of manufacturing a high power vertical GaN-PIN diode, comprising the steps of:
(1) providing a semiconductor laminated layer or a heterogeneous substrate; and
(2) forming a platform on the semiconductor laminated layer or the heterogeneous substrate.

2. The method according to claim 1, wherein the semiconductor laminated layer or the heterogeneous substrate comprises an upper block and a lower block; the lower block is the platform and abuts upon an upper surface of the semiconductor laminated layer or the heterogeneous substrate; and the upper block is a diode layer of a high power vertical gallium nitride PIN and is continuously and integrally formed with the semiconductor laminated layer or the heterogeneous substrate.

3. The method according to claim 1, wherein an Ohmic contact and high concentration (1×10¹⁹ cm⁻³) N-type gallium nitride semiconductor laminated layer is selected from the group consisting of Ti, Al, Au (with the thickness of 250 Å/125 Å/350 Å/375 Å) and an alloy thereof, and a high concentration (1×10¹⁸ cm⁻³) P-type gallium nitride semiconductor laminated layer is selected from the group consisting of Ni, Au (with the thickness 50 Å/200 Å) and an alloy thereof.

4. A method of manufacturing a high power vertical GaN-PIN diode, comprising:
providing a semiconductor laminated layer or a heterogeneous substrate;
forming a platform of the high power vertical GaN-PIN diode on the semiconductor laminated layer or the heterogeneous substrate;
constituting the high power vertical GaN-PIN diode on the semiconductor laminated layer or the heterogeneous substrate; and
forming a heterogeneous epitaxy region on the semiconductor laminated layer or the heterogeneous substrate;
wherein the semiconductor laminated layer or the heterogeneous substrate comprise an upper block and a lower block; the lower block is the platform and abuts upon an upper surface of the semiconductor laminated layer or the heterogeneous substrate; and the upper block is a diode layer of a high power vertical gallium nitride PIN, which is continuously and integrally formed with the semiconductor laminated layer or the heterogeneous substrate.

5. The method according to claim 4, wherein the platform is a low Ohmic contact layer (N or P) obtained through a sputter or a thermal evaporation deposition.

6. The method according to claim 5, wherein a reverse breakdown voltage of the diode is higher than or equal to 600 V, and an on-resistance of the diode is lower than or equal to 5 mΩ-cm².
